(19) United States
(12) Patent Application Publication
(10) Pub. No.: US 2024/0356495 A1
(43) Pub. Date: Oct. 24, 2024

(54) PHASE COMPENSATION FOR EFFICIENCY IMPROVEMENT FOR RF POWER AMPLIFIER

(71) Applicant: Spreadtrum Communications USA Inc., San Jose, CA (US)

(72) Inventor: Jason X. Deng, Greensboro, NC (US)

(21) Appl. No.: 18/136,479

(22) Filed: Apr. 19, 2023

(51) Int. Cl. H03F 1/02; H03F 3/21

(52) U.S. Cl. CPC H03F 1/0288; H03F 3/211; H03F 2200/387; H03F 2200/451

(57) ABSTRACT

A method for amplifying an RF signal is provided. The method includes providing the RF signal to an input of a quadrature coupler. The method includes outputting, from the quadrature coupler, a carrier path signal and a peak path signal. The method includes amplifying the carrier path signal to provide an amplified carrier path signal and amplifying the peak path signal to provide an amplified peak path signal. The method includes generating a first neutralizing signal based on the carrier path signal and generating a second neutralizing signal based on the peak path signal. The method includes modifying the amplified peak path signal based on the first neutralizing signal to provide a neutralized peak path signal and modifying the amplified carrier path signal based on the second neutralizing signal to provide a neutralized carrier path signal. The method also includes combining the neutralized carrier path and peak path signals.

### BACKGROUND

In wireless communication devices, a radio frequency (RF) front end module processes modulated RF signals that are received from an antenna or to be transmitted by an antenna. In the transmission path, an RF front end module often has an RF power amplifier having one or more stages of power amplification that amplify the power of the RF signals to a level suitable for transmission. The performance of an RF power amplifier can be evaluated by a variety of metrics, such as gain, efficiency, linearity, and harmonic leakage.

### SUMMARY

The subject matter disclosed herein relates to techniques for improving the efficiency, e.g., power added efficiency (PAE), of a RF power amplifier, such as a Doherty power amplifier. An RF power amplifier implemented according to the disclosed techniques utilizes neutralization paths between a carrier path and a peak path of a Doherty amplifier to offset parasitic capacitance in the circuit and thereby achieve high gain at the output stage. The increased output stage gain can improve the overall PAE of the RF power amplifier such that fewer driver stages are needed. The reduced number of driver stages can lead to a reduced size of the RF power amplifier circuit.

In general, in some aspects, the subject matter of the present disclosure can be embodied in an electronic circuit, such as a power amplifier circuit of an RF front end circuit. The electronic circuit includes: a quadrature coupler arranged to receive an RF signal and configured to output a carrier path signal and a peak path signal; a carrier amplification circuit arranged to receive the carrier path signal and configured to generate an amplified carrier path signal; a peak amplification circuit arranged to receive the peak path signal and configured to generate an amplified peak path signal; a first neutralization circuit arranged between an input of the carrier amplification circuit and an output of the peak amplification circuit; a second neutralization circuit electrically arranged between an input of the peak amplification circuit and an output of the carrier amplification circuit; and a combiner circuit. The first neutralization circuit is configured to generate a first neutralizing signal and modify the amplified peak path signal based on the first neutralizing signal to obtain a neutralized peak path signal. The second neutralization circuit is configured to generate a second neutralizing signal and modify the amplified carrier path signal based on the second neutralizing signal to obtain a neutralized carrier path signal. The combiner circuit is configured to combine the neutralized carrier path signal and the neutralized peak path signal.

In some implementations, the quadrature coupler is configured to offset the carrier path signal from the peak path signal by +90° in phase, the first neutralization circuit includes a +90° phase shifter, and the second neutralization circuit includes a −90° phase shifter. Alternatively, the quadrature coupler is configured to offset the carrier path signal from the peak path signal by −90° in phase, the first neutralization circuit includes a −90° phase shifter, and the second neutralization circuit includes a +90° phase shifter.

In some implementations, the first neutralization circuit includes a first neutralization capacitor, and the second neutralization circuit includes a second neutralization capacitor.

In some implementations, a first capacitance value of the first neutralization capacitor and a second capacitance value of the second neutralization capacitor are determined according to at least one of: a frequency of the RF signal, a device size of the electronic circuit, an amplification gain of the electronic circuit, or a stability of the electronic circuit.

In some implementations, the combiner circuit includes a quarter-wave length phase shifter connected in series with either the peak amplification circuit or the carrier amplification circuit according to a type of combination, the type including at least one of voltage combination or current combination.

In some implementations, the electronic circuit further includes a driver circuit. The driver circuit includes an input matching circuit and at least one stage of power amplification. The input matching circuit is arranged to receive an input signal. The driver circuit is configured to generate the RF signal by amplifying the input signal using the at least one stage of power amplification.

In some implementations, wherein each stage of the at least one stage of power amplification includes a corresponding power amplifier and a corresponding interstage matching circuit connected in series.

In some implementations, the carrier amplification circuit includes one or more carrier amplification bipolar junction transistors (BJTs), and the peak amplification circuit includes one or more peak amplification BJTs.

In some implementations, the electronic circuit further includes an output matching circuit electrically coupled the combiner circuit.

In some aspects, the subject matter of the present disclosure can be embodied in a method for amplifying an RF signal. The method includes providing the RF signal to an input of a quadrature coupler. The method includes outputting, from the quadrature coupler, a carrier path signal and a peak path signal. The method includes amplifying the carrier path signal to provide an amplified carrier path signal and amplifying the peak path signal to provide an amplified peak path signal. The method includes generating a first neutralizing signal based on the carrier path signal and generating a second neutralizing signal based on the peak path signal. The method includes modifying the amplified peak path signal based on the first neutralizing signal to provide a neutralized peak path signal and modifying the amplified carrier path signal based on the second neutralizing signal to provide a neutralized carrier path signal. The method also includes combining the neutralized carrier path and peak path signals.

In some implementations, the carrier path signal leads the peak path signal by 90°. Generating the first neutralizing signal includes connecting a +90° phase shifter and a first neutralization capacitor in series to obtain a first neutralization circuit, and providing the carrier path signal to the first neutralization circuit to obtain the first neutralizing signal. Generating the second neutralizing signal includes connecting a −90° phase shifter and a second neutralization capacitor in series to obtain a second neutralization circuit, and providing the peak path signal to the second neutralization circuit to obtain the second neutralizing signal. Modifying the amplified peak path signal includes coupling the first neutralizing signal to the amplified peak path signal. Modifying the amplified carrier path signal includes coupling the second neutralizing signal to the amplified carrier path signal.

In some implementations, the peak path signal leads the carrier path signal by 90°. Generating the first neutralizing signal includes connecting a −90° phase shifter and a first neutralization capacitor in series to obtain a first neutralization circuit, and providing the carrier path signal to the first neutralization circuit to obtain the first neutralizing signal. Generating the second neutralizing signal includes connecting a +90° phase shifter and a second neutralization capacitor in series to obtain a second neutralization circuit, and providing the peak path signal to the second neutralization circuit to obtain the second neutralizing signal. Modifying the amplified peak path signal includes coupling the first neutralizing signal to the amplified peak path signal. Modifying the amplified carrier path signal includes coupling the second neutralizing signal to the amplified carrier path signal.

In some implementations, the method further includes determining a first capacitance value of the first neutralization capacitor and a second capacitance value of the second neutralization capacitor according to at least one of: a frequency of the RF signal, a device size, an amplification gain, or a circuit stability.

In some implementations, combining the neutralized carrier path signal and the neutralized peak path signal includes: phase-shifting, using a quarter-wave length phase shifter, either the neutralized carrier path signal or the neutralized peak path signal according to a type of combination, the type including at least one of voltage combination or current combination.

In some implementations, the method further includes: receiving an input signal; amplifying the input signal using a driver circuit including at least one stage of power amplification; and obtaining the RF signal from the driver circuit.

In some implementations, the method further includes: obtaining a combined RF signal; and providing the combined RF signal to an output matching circuit.

The details of one or more implementations are set forth in the accompanying drawings and the description below. Other features, objects, and advantages of these systems and methods will be apparent from the description and drawings, and from the claims.

### BRIEF DESCRIPTION OF THE DRAWINGS

FIG. 1 is a schematic diagram of an example of a wireless communication system, according to some implementations.

FIG. 2 is a block diagram of example details of a wireless device, according to some implementations.

FIG. 3 is a graph showing a simulated relationship between an output stage gain and PAE.

FIG. 4 is a schematic diagram of an example circuit of a power amplification stage, according to some implementations.

FIG. 5A is a schematic diagram of an example RF power amplifier circuit, according to some implementations.

FIG. 5B is a schematic diagram of another example RF power amplifier circuit, according to some implementations.

FIG. 6 shows two graphs to provide a simulated comparison of Doherty load modulation performance with and without neutralization circuits, according to some implementations.

FIG. 7 is a graph showing a simulated relationship between the effect of parasitic capacitance neutralization and the impedance of the phase shifter in a neutralization circuit, according to some implementations.

FIG. 8 is a flowchart of an example method for amplifying an RF signal, according to some implementations.

### DETAILED DESCRIPTION

For RF power amplifiers with multiple stages of power amplification, the last stage is an output stage, while the other stages are collectively referred to as driver stages. The output stage is usually where a large amount of amplification (e.g., gain) is achieved, while each of the driver stages, due to circuit design constraints, usually contributes less to the overall gain. For each stage of amplification, higher gain usually means higher efficiency of power amplification. In many applications of mobile technologies, such as mobile phones, it is desirable to have high power amplification efficiency because of limited power supply.

Many RF power amplifiers operate at a power level often referred to as the backoff power. The backoff power of an RF power amplifier is a power level below the saturation point of the RF power amplifier. Having the RF power amplifier operate at the backoff power instead of at the saturation point can help keep the RF power amplifier operating in the linear range even at occasions when the power of the input signal reaches a level (e.g., a peak level) that is higher than the average power level. However, the efficiency of an RF power amplifier tends to decrease when the RF power amplifier operates at a lower power level than the saturation point. Some communication technologies use signals whose power has high peak-to-average ratio, e.g., 10 dB for orthogonal frequency-division multiplexing (OFDM) signals. In these scenarios, the backoff power can be considerably lower than the saturation point, which leads to considerable decrease in average efficiency.

Doherty amplifiers can be effective in increasing power amplification efficiency at the backoff power, in particular at the output stage. A Doherty amplifier divides an RF signal into two paths with a phase difference of 90°, uses a main amplifier (also known as a carrier amplifier) and a peak amplifier to separately amplify the divided signals, and combine the two paths after amplification. While Doherty amplifiers can increase power amplification efficiency at the backoff power thanks to load modulation provided by the peak amplifier, Doherty amplifiers can experience extra power loss and reduced efficiency at the peak power due to parasitic capacitance associated with the transistors in each path.

As described in detail below, implementations of this disclosure utilize neutralization paths to modify the amplified signals on the carrier path and the peak path by effectively reducing or canceling the parasitic capacitance on each path. As a result of such neutralization, RF power amplifiers implemented according to this disclosure can, in some cases, have increased gain at the output stage, and, consequently, increased power efficiency of one or more stages of the power amplifier combined. With the increased output stage gain, the number of driver stages can, in some implementations, be reduced, resulting in smaller circuit size and lower manufacturing complexity and cost.

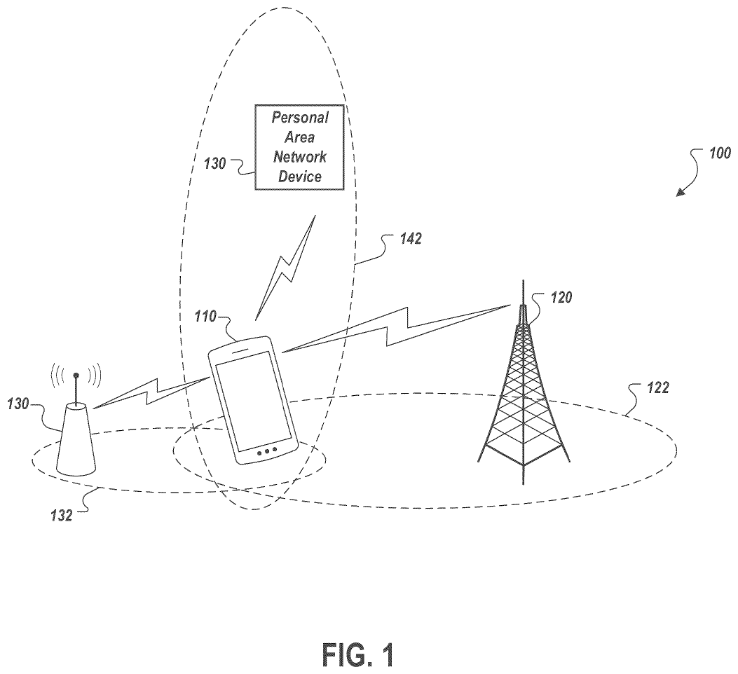

FIG. 1 is a schematic diagram of an example wireless communication system 100 including a wireless device 110 capable of communicating with one or more wireless communication networks. The one or more wireless communication networks with which the wireless device 110 is capable of communicating can include but is not limited to one or more cellular or wireless wide area networks (WWANs), one or more wireless local area networks (WLANs), one or more wireless personal area networks (WPANs), or a combination thereof.

In the example of FIG. 1, the wireless device 110 is communicating with at least one WWAN by way of at least one base station 120 and at least one WLAN by way of at least one access point 130. The at least one base station 120 can support bi-directional communication with wireless devices that are within its corresponding area of coverage 122. Similarly, the at least one access point 130 can support bi-directional communication with wireless devices that are within its corresponding area of coverage 132.

In some implementations, the at least one WWAN with which the at least one base station 120 is associated can be a fifth generation (5G) network among other generations and types of networks. In these implementations, the at least one base station 120 can be a 5G base station that employs orthogonal frequency-division multiplexing (OFDM) and/or non-OFDM and a transmission time interval (TTI) shorter than 1 ms (e.g. 100 or 200 microseconds), to communicate with wireless devices, such as wireless device 110. For example, the at least one base station 120 can take the form of one of several devices, such as a base transceiver station (BTS), a Node-B (NodeB), an evolved NodeB (eNB), a next (fifth) generation (NR) NodeB (gNB), a Home NodeB, a Home eNodeB, a site controller, an access point, a wireless router, a server, router, switch, or other processing entity with a wired or wireless network.

System 100 can use multiple channel access functionality, including for example schemes in which the at least one base station 120 and the wireless device 110 are configured to implement the Long Term Evolution wireless communication standard (LTE), LTE Advanced (LTE-A), and/or LTE Multimedia Broadcast Multicast Service (MBMS). In other implementations, the at least one base station 120 and wireless device 110 are configured to implement UMTS, HSPA, or HSPA+ standards and protocols. Of course, other multiple access schemes and wireless protocols can be utilized. In some examples, one or more such access schemes and wireless protocols can correspond to standards that impose RF power amplifier linearity requirements.

In addition, and as shown in FIG. 1, the wireless device 110 is configured to communicate with one or more personal area network (PAN) devices/systems 130 (e.g., Bluetooth® or radio frequency identification (RFID) systems and devices) over one or more WPANs. The one or more PAN devices/systems 130 can support either one-way or bi-directional communication with wireless devices that are within its corresponding area of coverage 142.

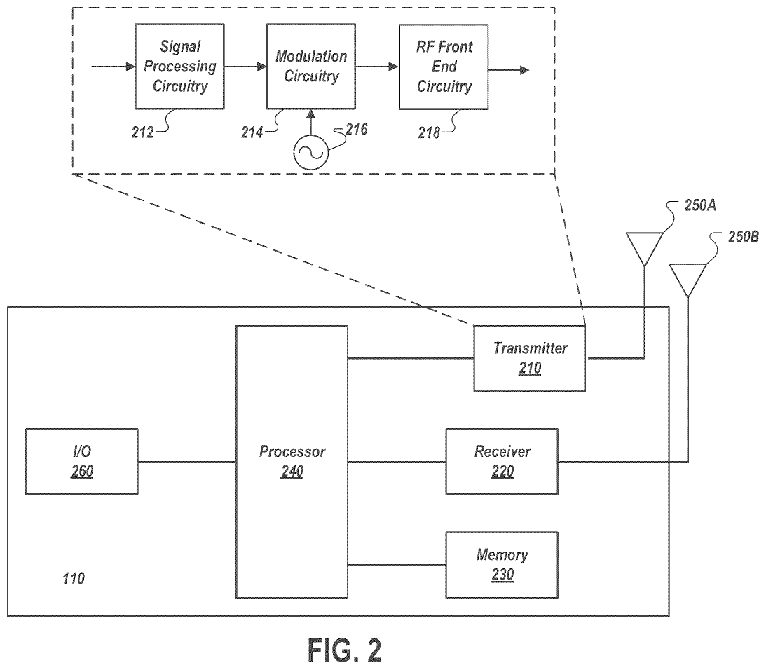

To communicate with one or both of the at least one base station 120 and the access point 130, the wireless device 110 can include singular or multiple transmitter and receiver components similar or equivalent to one or more of those described in further detail below with reference to FIG. 2 to support multiple communications with different types of access points, base stations, and other wireless communication devices.

Although FIG. 1 illustrates one example of a communication system, various changes can be made to FIG. 1. For example, the communication system 100 could include any number of wireless devices, base stations, access points, networks, or other components in any suitable configuration.

FIG. 2 is a block diagram that illustrates example details of the wireless device 110 that can implement the subject matter according to this disclosure. The wireless device 110 can, for example, be a mobile telephone, but can be other devices in further examples such as a desktop computer, laptop computer, tablet, hand-held computing device, automobile computing device and/or other computing devices. As shown in the figure, the wireless device 110 is shown as including at least one transmitter 210, at least one receiver 220, memory 230, at least one processor 240, and at least one input/output device 260. Here, only one transmitter and only one receiver are shown, but in many implementations, multiple transmitters and receivers are included to support multiple communications of different types at the same time. Each transmitter may employ the innovations of the present disclosure.

The processor 240 can implement various processing operations of the wireless device 110. For example, the processor 240 can perform signal generation, signal coding, signal analysis, data processing, power control, input/output processing, or any other functionality enabling the wireless device 110 to operate in a communication system, such as system 100 (FIG. 1). The processor 240 can include any suitable processing or computing device configured to perform one or more operations. For example, the processor 240 can include a microprocessor, microcontroller, digital signal processor, field programmable gate array, or application specific integrated circuit, or a combination of these devices.

The transmitter 210 can be configured to modulate data or other content, filter and amplify outgoing RF signals for transmission by at least one antenna 250A. In some implementations, the transmitter 210 can also be configured to amplify, filter and upconvert baseband or intermediate frequency (IF) signals to RFs signals before such signals are provided to the antenna 250A for transmission. The transmitter 210 can include any suitable structure for generating RF signals for wireless transmission. Additional aspects of the transmitter 210 are described in further detail below with reference to components 212-218 as depicted in FIG. 2.

The receiver 220 can be configured to demodulate data or other content received in incoming RF signals by at least one antenna 250B. In some implementations, the receiver 220 can also be configured to amplify, filter and frequency down convert RF signals received via the antenna 250B either to IF or baseband frequency signals prior to conversion to digital form and processing. The receiver 220 can include any suitable structure for processing signals received wirelessly.

Each of the antennas 250A and 250B can include any suitable structure for transmitting and/or receiving wireless RF signals. In some implementations, the antennas 250A and 250B can be implemented by way of a single antenna that can be used for both transmitting and receiving RF signals.

One or multiple transmitters 210, one or multiple receivers 220, and one or multiple antennas 250 could be used in the wireless device 110. For example, in one implementation, device 110 includes at least three transmitters 210 and at least three receivers 220 for communicating via at least a personal area network such as Bluetooth®, a Wi-Fi network such as an IEEE 802.11 based network, and a cellular network. Each transmitter 210 may employ the concepts of the present disclosure. Although shown as separate blocks or components, at least one transmitter 210 and at least one receiver 220 could be combined into a transceiver. Each transceiver may employ the concepts of the present disclosure. Accordingly, rather than showing a separate block for the transmitter 210 and a separate block for the receiver 220 in FIG. 2, a single block for a transceiver could have been shown.

The wireless device 110 further includes one or more input/output devices 260. The input/output devices 260 facilitate interaction with a user. Each input/output device 260 includes any suitable structure for providing information to or receiving information from a user, such as a speaker, microphone, keypad, keyboard, display, and/or touch screen.

In addition, the wireless device 110 includes at least one memory 230. The memory 230 stores instructions and data used, generated, and/or collected by the wireless device 110. For example, the memory 230 could store software or firmware instructions executed by the processor(s) 240 and data used to reduce or eliminate interference in incoming signals. Each memory 230 includes any suitable volatile and/or non-volatile storage and retrieval device(s). Any suitable type of memory may be used, such as random access memory (RAM), read only memory (ROM), hard disk, optical disc, subscriber identity module (SIM) card, memory stick, secure digital (SD) memory card, and the like.

In some implementations, the transmitter 210 can include signal processing circuitry 212, modulation circuitry 214, and RF front end circuitry 218. The signal processing circuitry 212 may include one or more circuits that are configured to process signals received as input (e.g. from processor 240). For example, the signal processing circuitry 212 may include a digital-to-analog converter (D/A), which converts a digital input (e.g. a digital signal from processor 240) into an analog signal, which is then provided to a low pass filter, which filters the analog signal and provides the filtered analog signal to the modulation circuitry 214. The modulation circuitry 214, in addition to receiving the filtered analog signal from the signal processing circuitry 212, can, in some implementations, also receive a signal from a local oscillator 216 for modulating or adjusting the frequency of the analog signal, e.g., from a first frequency to a second frequency that is higher than the first frequency. For instance, the modulation circuitry 214 can include a mixer that frequency up-converts the filtered analog signal from a relatively low frequency (e.g. baseband frequency, or an IF that is offset from the baseband frequency) to a relatively high frequency RF signal. Thus, a signal from the local oscillator 216 is used as a carrier signal in transmitter 210. Moreover, as shown in FIG. 2, transmitter 210 includes RF front end circuitry 218, which can include, e.g., amplification and filtering circuits that amplify and filter, respectively, the RF signal. The RF front end circuitry can also include a power amplifier that is configured to provide sufficient amplification of the signal to meet transmission requirements, as may be specified by wireless communication standards. Examples of such standards include those set forth by the 3rd Generation Partnership Project (3GPP), which is a group that develops standards for cellular telecommunications technologies, including radio access, core network, and service capabilities.

The RF signal amplified by the power amplifier may be filtered again by at least one additional filter downstream of the power amplifier before being provided as an output of the transmitter 210 to the at least one antenna 250A for wireless transmission. Such filter or filters can alternatively be provided upstream from the power amplifier in which case the output of the power amplifier is provided to the at least one antenna 250A for wireless transmission.

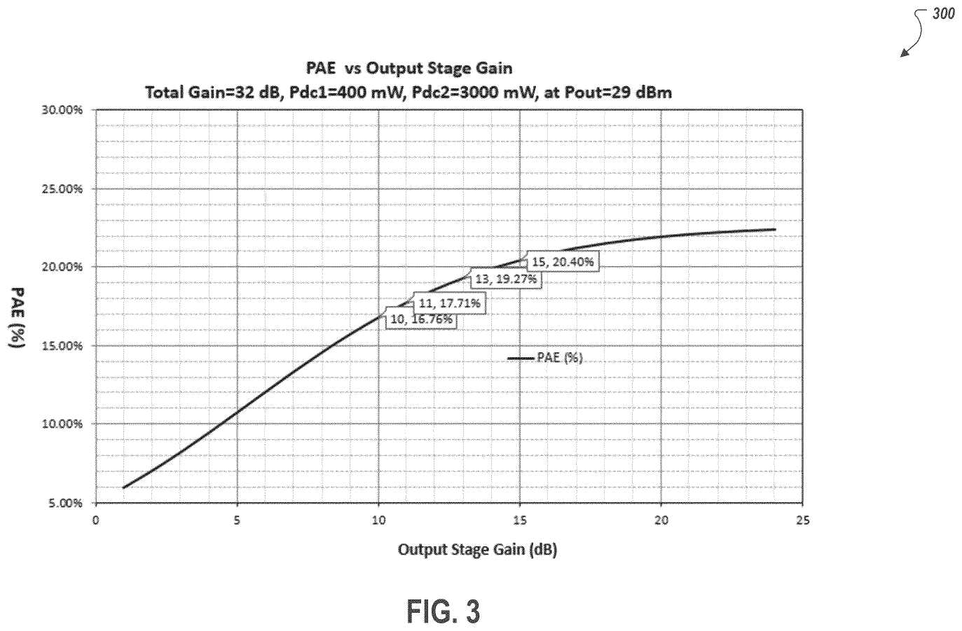

FIG. 3 is a graph 300 showing an example of a simulated relationship between an output stage gain and PAE of a two-stage amplifier. The simulation assumes that the total gain achieved by the driver stages and the output stage is 32 dB, with the output power being at 29 dbm. The simulation assumes that the driver stages and the output stage consume 400 mW and 3000 mW, respectively, of direct current (DC) power supply.

As shown on the graph 300, the PAE of the amplifier is positively correlated to the output stage gain. For example, with the output stage gain increasing from 10 dB to 15 dB, the PAE increases from about 16.76% to about 20.40%. Such positive correlation indicates that the efficiency can be achieved by increasing the output stage gain.

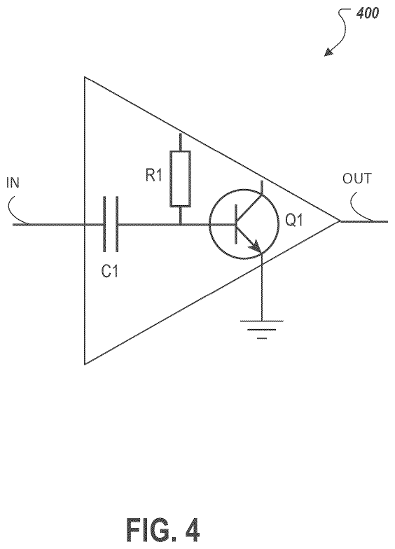

FIG. 4 is a schematic diagram of an example circuit 400 of a power amplification stage, according to some implementations. The circuit 400 receives an input RF signal IN and outputs an output RF signal OUT. The circuit 400 is formed using one or more BJTs Q1, one or more resistors R1, and one or more capacitors C1. R1 and C1 together form a bias circuit that provides a bias current to the collector of Q1 for amplification.

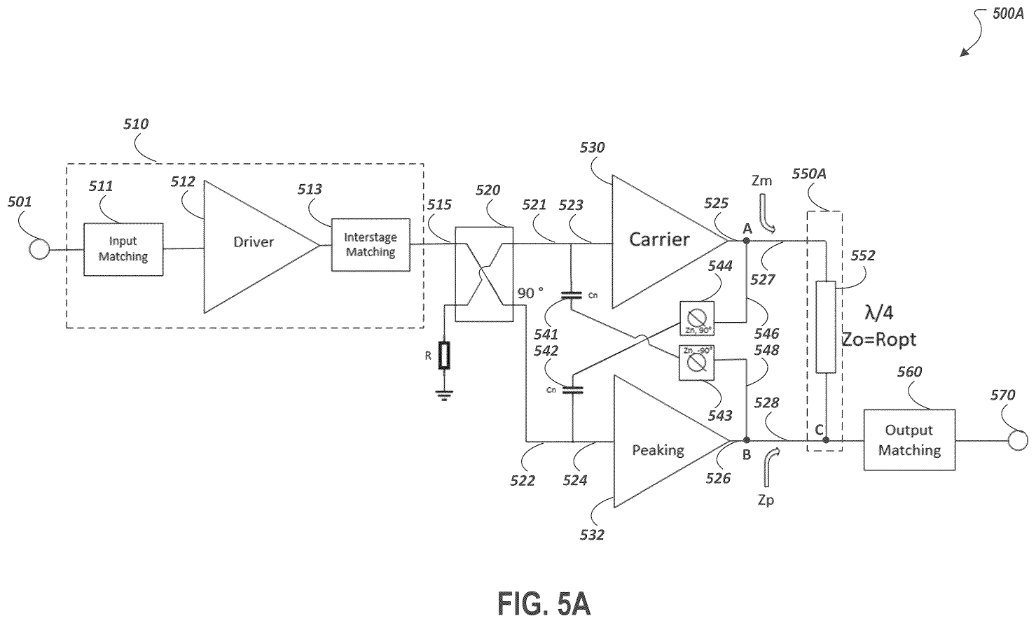

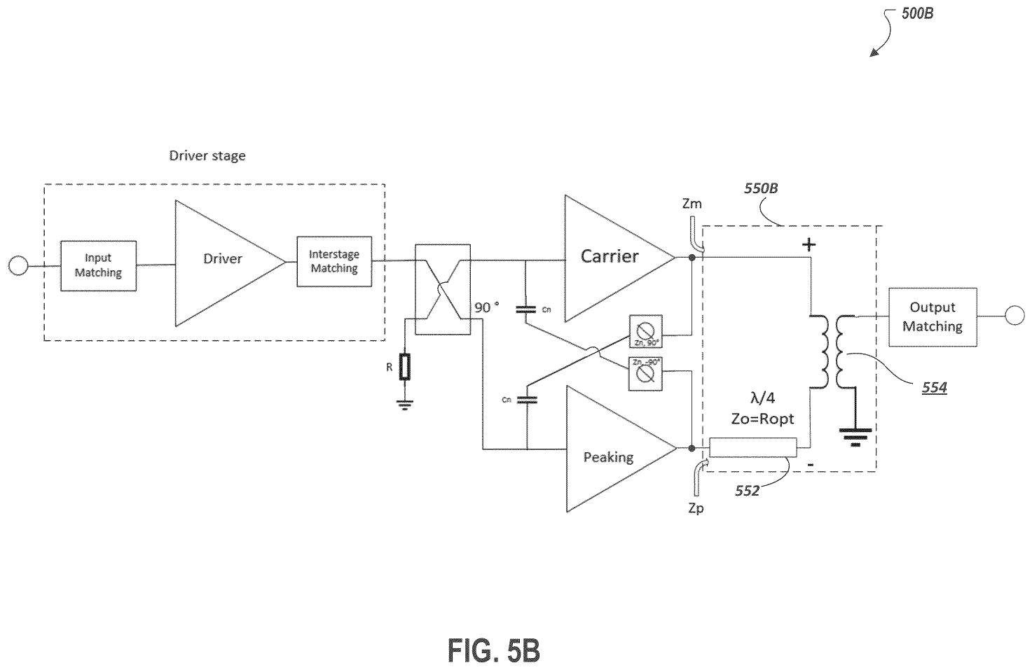

FIG. 5A is a schematic diagram of an example RF power amplifier circuit 500A, according to some implementations. The RF power amplifier circuit 500A can be implemented in, e.g., the RF front end circuitry 218 of FIG. 2. The RF power amplifier circuit 500A can be a Doherty power amplifier, which can have a carrier path output at node A and a peaking path output at node B. The relative phase difference between A and B can be +/−90°. For the purpose of neutralization (described below in detail), one or more phase shifters can be introduced in neutralization paths to accomplish a phase difference of 180°.

The RF power amplifier circuit 500A is configured to receive an input RF signal from the input port 501 (which can be coupled to an input port of the RF front end circuitry 218), amplify the RF signal, and output the amplified RF signal via the output port 570. To achieve the amplification, the RF power amplifier circuit 500A has a driver circuit 510 with one or more driver stages, and an output stage arranged between the driver circuit 510 and the output port 570.

Each driver stage includes a power amplifier 512 with an output coupled to an interstage matching circuit 513. The power amplifier 512 can have a BJT-based structure similar to that of the circuit 400. Alternatively or additionally, the power amplifier 512 can have a different structure, such as a Field-Effect Transistor (FET)-based structure, with different components from the circuit 400. The interstage matching circuit 513 provides impedance matching between two consecutive driver stages and between the last driver stage and the output stage. The driver circuit 510 also has an input matching circuit 511 that provides impedance matching between the input port 501 and the first driver stage. The interstage matching circuits 513 and the input matching circuit 511 together facilitate the propagation of RF signals from the input port 501 through the driver circuit 510 to the output stage.

The output stage of the RF power amplifier circuit 500A includes a quadrature coupler 520, a carrier amplification circuit 530, a peak amplification circuit 532, and a combiner circuit 550A. The quadrature coupler 520, carrier amplification circuit 530, peak amplification circuit 532, and combiner circuit 550A, along with the connections therebetween, form a basic structure of a Doherty amplifier. The quadrature coupler 520 receives an RF signal 512 from the driver circuit 510 and splits the RF signal 512 into a carrier path signal 521 and a peak path signal 522. In addition, the quadrature coupler 520 offsets the carrier path signal 521 from the peak path signal 522 by −90° in phase. In other words, the carrier path signal 521 lags behind the peak path signal 522 by 90° in phase. In some other implementations, the quadrature coupler 520 can instead offset the carrier path signal 521 from the peak path signal 522 by +90° in phase, causing the carrier path signal 521 to lead the peak path signal 522 by 90° in phase.

The carrier path signal 521 and the peak path signal 522 are input to the carrier amplification circuit 530 and the peak amplification circuit 532, respectively, for amplification. Each of the carrier amplification circuit 530 and the peak amplification circuit 532 can have a BJT-based structure similar to that of the circuit 400. Alternatively or additionally, each of the carrier amplification circuit 530 and the peak amplification circuit 532 can have a different structure, such as a Field-Effect Transistor (FET)-based structure, with different components from the circuit 400.

The combiner circuit 550A combines the amplification outputs from the carrier amplification circuit 530 and the peak amplification circuit 532 and provide the combination outcome to the output port 570. The combination provided by the combiner circuit 550A can be considered of a type of current combining, where the current from the carrier path and the current from the peak path are added (e.g., via an RF coupler) at node C. An output matching circuit 560 can be arranged between the combiner circuit 550A and the output port 570 to provide impedance matching between the two.

The combiner circuit 550A can include a quarter-wave length phase shifter 552 (e.g., a transmission line with impedance set to provide a +90° phase shift) connected in series with the carrier amplification circuit 530. For example, in implementations where the carrier path signal 521 lags behind the peak path signal 522 by 90° in phase, the quarter-wave length phase shifter 552 can be connected in series with the carrier amplification circuit 530 to compensate for the −90° phase difference imposed by the quadrature coupler 520 between the carrier path signal 521 and the peak path signal 522. With the phase compensation, the currents on the two paths are again in phase when combined at node C.

The output stage of the RF power amplifier circuit 500A further includes two neutralization circuits. A first neutralization circuit is arranged between an input 523 of the carrier amplification circuit 530 and an output 526 of the peak amplification circuit 532. A second neutralization circuit is arranged between an input 524 of the peak amplification circuit 532 and an output 525 of the carrier amplification circuit 530. The first neutralization circuit includes a first neutralization capacitor 541 and a first phase shifter 543, connected in series. The second neutralization circuit includes a second neutralization capacitor 542 and a second phase shifter 544, connected in series. Although FIG. 5A shows that a branch of the carrier path signal 521 flows through the first neutralization capacitor 541 first and the first phase shifter 543 second, the RF power amplifier circuit 500A contemplates swapping the positions of the first neutralization capacitor 541 and the first phase shifter 543 such that the branch of the carrier path signal 521 flows through the first phase shifter 543 first and the first neutralization capacitor 541 second. Likewise, although FIG. 5A shows that a branch of the peak path signal 522 flows through the second neutralization capacitor 542 first and the second phase shifter 544 second, the RF power amplifier circuit 500A contemplates swapping the positions of the second neutralization capacitor 542 and second first phase shifter 544 such that the branch of the peak path signal 522 flows through the second phase shifter 544 first and second first neutralization capacitor 542 second.

In implementations where the carrier path signal 521 lags behind the peak path signal 522 by 90° in phase, the first phase shifter 543 is a −90° phase shifter and the second phase shifter 544 is a +90° phase shifter. As such, when a branch of the carrier path signal 521 flows through the first neutralization circuit, the first phase shifter 543 imposes an additional −90° phase shift to the branch. As a result, the first neutralization circuit generates a first neutralizing signal 548 that differs from the peak path signal 522 by 180° in phase. Likewise, when a branch of the peak path signal 522 flows through the second neutralization circuit, the second phase shifter 544 imposes an additional +90° phase shift to the branch. As a result, the second neutralization circuit generates a second neutralizing signal 546 that differs from the carrier path signal 521 by 180° in phase.

In alternative implementations where the carrier path signal 521 leads the peak path signal 522 by 90° in phase, the first phase shifter 543 is a +90° phase shifter and the second phase shifter 544 is a −90° phase shifter. With the phase shift provided by the first and second phase shifters 543 and 544, the first and second neutralizing signals 548 and 546 in these implementations also differ from the peak path signal 522 and the carrier path signal 521, respectively, by 180° in phase.

The first and second neutralizing signals 548 and 546 are provided to the peak path and the carrier path, respectively, to neutralize (e.g., cancel or reduce) the parasitic capacitance associated with amplifying transistors of the carrier amplification circuit 530 and the peak amplification circuit 532. Taking the first neutralizing signal 548 as an example, the first neutralizing signal 548 is coupled with an amplified peak path signal output by the peak amplification circuit 532 at output 526. The coupling can modify the amplified peak path signal to generate a neutralized peak path signal 528. Similarly, the second neutralizing signal 546 is coupled with and thereby modifies an amplified carrier path signal to generate a neutralized carrier path signal 527.

Compared with Doherty amplifiers that do not have neutralization circuits, a Doherty RF power amplifier modified in accordance with circuit 500A can, by way of modifying the amplified carrier path and peak path signals, neutralize the parasitic capacitance associated with amplifying transistors of the carrier amplification circuit 530 and the peak amplification circuit 532 on each path. The neutralization can be attributed to the impedance introduced by the neutralization capacitors and the phase shifters of the neutralization circuits.

The tuning of the capacitance of the first and second neutralization capacitors 541 and 542 can consider a number of factors or constraints, such as the frequency of the RF signal 515, the size of RF power amplifier circuit 500A (or, separately, the size of the output stage), the gain of the RF power amplifier circuit 500A (or, separately, the target gain of the output stage), and the stability of the RF power amplifier circuit 500A. Similarly, the tuning of the characteristic impedance of the first and second phase shifters 543 and 544 can consider a number of factors or constraints with a goal of achieving the needed neutralization effect while reducing unwanted impact to Doherty load modulation.

FIG. 5B is a schematic diagram of another example RF power amplifier circuit 500B, according to some implementations. The RF power amplifier circuit 500B can be substantially the same as the RF power amplifier circuit 500A except for having a combiner circuit 550B that is different from the combiner circuit 550A. For the sake of brevity, description of the RF power amplifier circuit 500B is only focused on the combiner circuit 550B, while the description and numbering of other components of the RF power amplifier circuit 500B, which can be the same as those of the RF power amplifier circuit 500A, are omitted.

Different from the combiner circuit 550A that combines currents from the carrier path and the peak path, the combiner circuit 550B uses a RF transformer 554 for voltage combining. In voltage combining, two signals with a phase difference of 180° are input to the “+” and “−” input ports of the transformer 554, whose output port, in some implementations, can be coupled to a matching circuit and further to amplifier output. This type of voltage combining also uses a quarter-wave length phase shifter 552 (e.g., a transmission line with optimized impedance set to provide a +90° phase shift). For example, in implementations where the carrier path signal lags behind the peak path signal by 90° in phase, the quarter-wave length phase shifter 552 can be connected in series with the peak amplification circuit such that the signals at the “+” and “−” input ports of the transformer 554 are 180° different in phase.

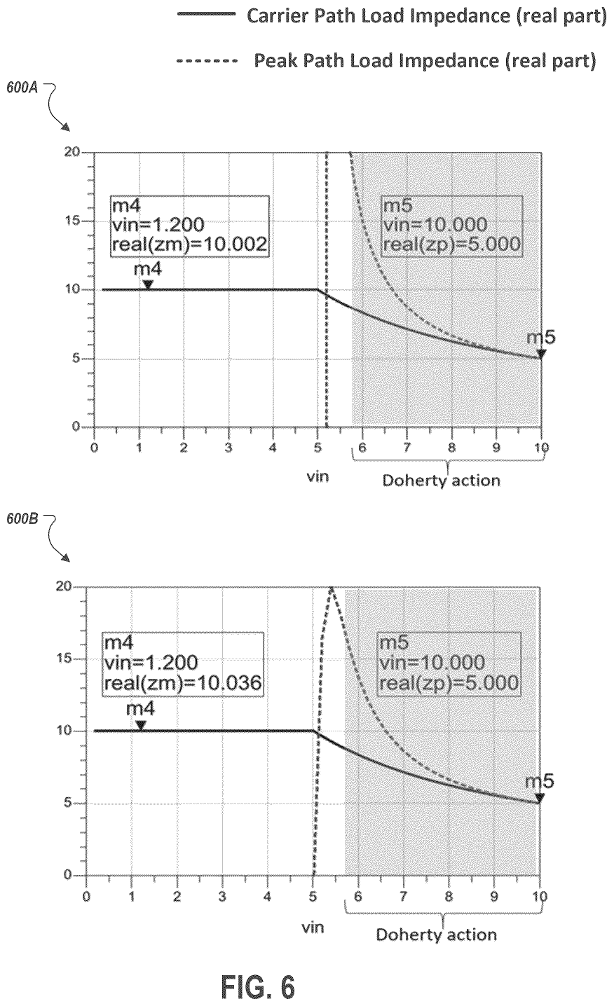

FIG. 6 shows two graphs 600A and 600B that show a simulated comparison of Doherty load modulation (“Doherty action”) performance with and without neutralization circuits, according to some implementations. The load modulation can be evaluated based on the real parts (e.g., resistive component) of effective impedance Zₘ and Zₚ on the carrier path and the peak path, respectively. Graph 600A shows the ideal Doherty load modulation performance without neutralization circuits, while Graph 600B shows the Doherty load modulation performance with neutralization circuits. Both graphs assume the input voltage to the Doherty amplifier is 1.2 V.

As shown in the graphs 600A and 600B, Doherty load modulation can be maintained with proper tuning of Zₘ and Zₚ, which can be adjusted by tuning the impedance of the neutralization circuits. This comparison shows that implementations described herein can be applied to Doherty power amplifiers without significant compromises to the proper functioning thereof.

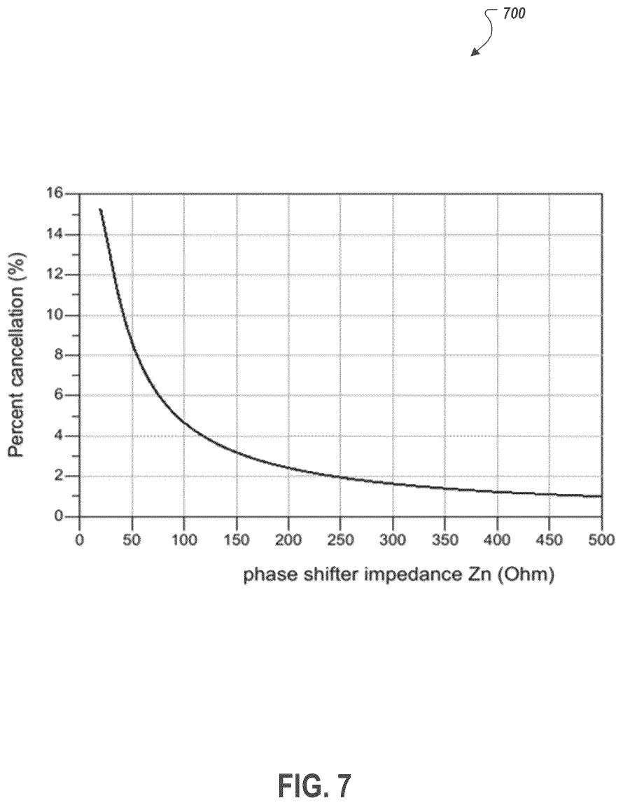

FIG. 7 is a graph 700 showing a simulated relationship between the effect of parasitic capacitance neutralization and the impedance of the phase shifter in a neutralization circuit, according to some implementations. The vertical axis shows the percentage of the parasitic capacitance that is cancelled by the neutralization circuit, and the horizontal axis shows the impedance of the phase shifter in the neutralization circuit. As shown in the graph 700, the neutralization circuit performs better when the phase shifter has low impedance. The relationship shown in the graph 700 can be used to design neutralization circuits, such as those shown in FIGS. 5A and 5B.

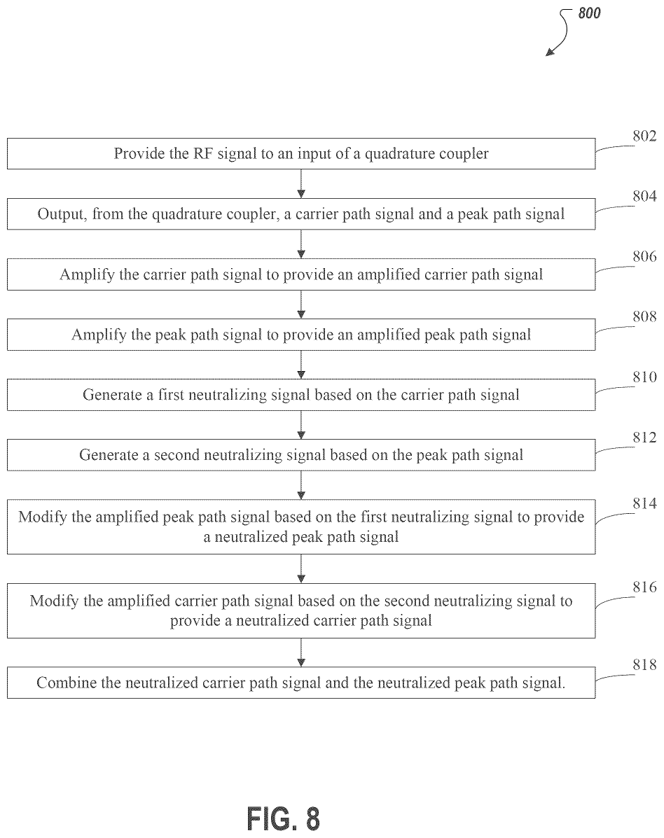

FIG. 8 is a flowchart of an example method for amplifying an RF signal, according to some implementations. It would be understood that the method 800 can be performed, for example, by any suitable system, environment, software, hardware, or a combination of systems, environments, software, and hardware, as appropriate. In some implementations, various steps of the method 800 can be run in parallel, in combination, in loops, or in any order. The method 800 can be embodied in a circuit similar to circuits 500A and 500B of FIGS. 5A and 5B. For example, some signals and circuit components can be similar to the corresponding signals and circuit components of circuits 500A and 500B. Alternatively or additionally, some operations of the method 800 can be performed by one or more circuit components of circuits 500A and 500B.

At 802, the method 800 involves providing the RF signal to an input of a quadrature coupler (e.g., the quadrature coupler 520).

At 804, the method 800 involves outputting, from the quadrature coupler, a carrier path signal (e.g., the carrier path signal 521) and a peak path signal (e.g., the peak path signal 522).

At 806, the method 800 involves amplifying (e.g., using the carrier amplification circuit 530) the carrier path signal to provide an amplified carrier path signal.

At 808, the method 800 involves amplifying (e.g., using the peak amplification circuit 532) the peak path signal to provide an amplified peak path signal.

At 810, the method 800 involves generating a first neutralizing signal (e.g., the first neutralizing signal 548) based on the carrier path signal.

At 812, the method 800 involves generating a second neutralizing signal (e.g., the second neutralizing signal 546) based on the peak path signal.

At 814, the method 800 involves modifying the amplified peak path signal based on the first neutralizing signal to provide a neutralized peak path signal (e.g., the neutralized peak path signal 528).

At 816, the method 800 involves modifying the amplified carrier path signal based on the second neutralizing signal to provide a neutralized carrier path signal (e.g., the neutralized carrier path signal 527).

At 818, the method 800 involves combining (e.g., using the combiner circuits 550A or 550B) the neutralized carrier path signal and the neutralized peak path signal.

While features described above are primarily implemented by wireless devices, these features can likewise be implemented by access nodes, base stations, or other types fixed or portable wireless communication equipment and/or infrastructure. For example, a base station in communication with a cellular phone can have RF front end circuitry that implements the above-described features with respect to thermally adjustable DC bias circuit.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system modules and components in the implementations described above should not be understood as requiring such separation in all implementations, and it should be understood that the described program components and systems can generally be integrated together in a single software product or packaged into multiple software products.

In addition, techniques, systems, subsystems, and methods described and illustrated in the various implementations as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

For purposes of this document, a connection may be a direct connection or an indirect connection (e.g., via one or more other parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

Particular implementations of the subject matter have been described. Other implementations are within the scope of the following claims. For example, the actions recited in the claims can be performed in a different order and still achieve desirable results. As one example, the processes depicted in the accompanying figures do not necessarily require the particular order shown, or sequential order, to achieve desirable results.

What is claimed is:

1. An electronic circuit, comprising:
a quadrature coupler arranged to receive a radio frequency (RF) signal and configured to output a carrier path signal and a peak path signal;
a carrier amplification circuit arranged to receive the carrier path signal and configured to generate an amplified carrier path signal;
a peak amplification circuit arranged to receive the peak path signal and configured to generate an amplified peak path signal;
a first neutralization circuit arranged between an input of the carrier amplification circuit and an output of the peak amplification circuit, wherein the first neutralization circuit is configured to generate a first neutralizing signal and modify the amplified peak path signal based on the first neutralizing signal to obtain a neutralized peak path signal;
a second neutralization circuit electrically arranged between an input of the peak amplification circuit and an output of the carrier amplification circuit, wherein the second neutralization circuit is configured to generate a second neutralizing signal and modify the amplified carrier path signal based on the second neutralizing signal to obtain a neutralized carrier path signal; and
a combiner circuit configured to combine the neutralized carrier path signal and the neutralized peak path signal.

2. The electronic circuit of claim 1, wherein
the quadrature coupler is configured to offset the carrier path signal from the peak path signal by +90° in phase, the first neutralization circuit comprises a +90° phase shifter, and the second neutralization circuit comprises a −90° phase shifter, or
the quadrature coupler is configured to offset the carrier path signal from the peak path signal by −90° in phase, the first neutralization circuit comprises a −90° phase shifter, and the second neutralization circuit comprises a +90° phase shifter.

3. The electronic circuit of claim 2, wherein
the first neutralization circuit comprises a first neutralization capacitor, and
the second neutralization circuit comprises a second neutralization capacitor.

4. The electronic circuit of claim 3, wherein a first capacitance value of the first neutralization capacitor and a second capacitance value of the second neutralization capacitor are determined according to at least one of: a frequency of the RF signal, a device size of the electronic circuit, an amplification gain of the electronic circuit, or a stability of the electronic circuit.

5. The electronic circuit of claim 1, wherein the combiner circuit comprises a quarter-wave length phase shifter connected in series with either the peak amplification circuit or the carrier amplification circuit according to a type of combination, the type comprising at least one of voltage combination or current combination.

6. The electronic circuit of claim 1, further comprising a driver circuit, wherein
the driver circuit comprises an input matching circuit and at least one stage of power amplification,
the input matching circuit is arranged to receive an input signal, and
the driver circuit is configured to generate the RF signal by amplifying the input signal using the at least one stage of power amplification.

7. The electronic circuit of claim 5, wherein each stage of the at least one stage of power amplification comprises a corresponding power amplifier and a corresponding interstage matching circuit connected in series.

8. The electronic circuit of claim 1, wherein the carrier amplification circuit comprises one or more carrier amplification bipolar junction transistors (BJTs), and the peak amplification circuit comprises one or more peak amplification BJTs.

9. The electronic circuit of claim 1, further comprising an output matching circuit electrically coupled the combiner circuit.

10. A method for amplifying a radio frequency (RF) signal, comprising:
providing the RF signal to an input of a quadrature coupler;
outputting, from the quadrature coupler, a carrier path signal and a peak path signal;
amplifying the carrier path signal to provide an amplified carrier path signal;
amplifying the peak path signal to provide an amplified peak path signal;
generating a first neutralizing signal based on the carrier path signal;
generating a second neutralizing signal based on the peak path signal;
modifying the amplified peak path signal based on the first neutralizing signal to provide a neutralized peak path signal;
modifying the amplified carrier path signal based on the second neutralizing signal to provide a neutralized carrier path signal; and
combining the neutralized carrier path signal and the neutralized peak path signal.

11. The method of claim 10,
wherein the carrier path signal leads the peak path signal by 90°,
wherein generating the first neutralizing signal comprises connecting a +90° phase shifter and a first neutralization capacitor in series to obtain a first neutralization circuit, and providing the carrier path signal to the first neutralization circuit to obtain the first neutralizing signal,
wherein generating the second neutralizing signal comprises connecting a −90° phase shifter and a second neutralization capacitor in series to obtain a second neutralization circuit, and providing the peak path signal to the second neutralization circuit to obtain the second neutralizing signal,
wherein modifying the amplified peak path signal comprises coupling the first neutralizing signal to the amplified peak path signal, and
wherein modifying the amplified carrier path signal comprises coupling the second neutralizing signal to the amplified carrier path signal.

12. The method of claim 10, wherein
the peak path signal leads the carrier path signal by 90°,
wherein generating the first neutralizing signal comprises connecting a −90° phase shifter and a first neutralization capacitor in series to obtain a first neutralization circuit, and providing the carrier path signal to the first neutralization circuit to obtain the first neutralizing signal,
wherein generating the second neutralizing signal comprises connecting a +90° phase shifter and a second neutralization capacitor in series to obtain a second neutralization circuit, and providing the peak path signal to the second neutralization circuit to obtain the second neutralizing signal,
wherein modifying the amplified peak path signal comprises coupling the first neutralizing signal to the amplified peak path signal, and
wherein modifying the amplified carrier path signal comprises coupling the second neutralizing signal to the amplified carrier path signal.

13. The method of claim 11, further comprising:
determining a first capacitance value of the first neutralization capacitor and a second capacitance value of the second neutralization capacitor according to at least one of: a frequency of the RF signal, a device size, an amplification gain, or a circuit stability.

14. The method of claim 12, further comprising:
determining a first capacitance value of the first neutralization capacitor and a second capacitance value of the second neutralization capacitor according to at least one of: a frequency of the RF signal, a device size, an amplification gain, or a circuit stability.

15. The method of claim 10, wherein combining the neutralized carrier path signal and the neutralized peak path signal comprises:
phase-shifting, using a quarter-wave length phase shifter, either the neutralized carrier path signal or the neutralized peak path signal according to a type of combination, the type comprising at least one of voltage combination or current combination.

16. The method of claim 10, further comprising:
receiving an input signal;
amplifying the input signal using a driver circuit comprising at least one stage of power amplification; and
obtaining the RF signal from the driver circuit.

17. The method of claim 10, further comprising:
obtaining a combined RF signal; and
providing the combined RF signal to an output matching circuit.

18. A radio frequency (RF) front end circuit, comprising an input port and a power amplifier circuit, the power amplifier circuit comprising:
a quadrature coupler arranged to receive a radio frequency (RF) signal and configured to output a carrier path signal and a peak path signal;
a carrier amplification circuit arranged to receive the carrier path signal and configured to generate an amplified carrier path signal;
a peak amplification circuit arranged to receive the peak path signal and configured to generate an amplified peak path signal;
a first neutralization circuit arranged between an input of the carrier amplification circuit and an output of the peak amplification circuit, wherein the first neutralization circuit is configured to generate a first neutralizing signal and modify the amplified peak path signal based on the first neutralizing signal to obtain a neutralized peak path signal;
a second neutralization circuit electrically arranged between an input of the peak amplification circuit and an output of the carrier amplification circuit, wherein the second neutralization circuit is configured to generate a second neutralizing signal and modify the amplified carrier path signal based on the second neutralizing signal to obtain a neutralized carrier path signal; and
a combiner circuit configured to combine the neutralized carrier path signal and the neutralized peak path signal.
